(19) United States
(12) Patent Application Publication
(10) Pub. No.: US 2026/0269824 A1
(43) Pub. Date: Sep. 10, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Taichi FUKUDA, Yokohama Kanagawa (JP); Keigo ARITA, Kawasaki Kanagawa (JP); Tatsunori SAKANO, Shinagawa Tokyo (JP); Ryohei GEJO, Kawasaki Kanagawa (JP); Takato YAMAMOTO, Kawasaki Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/444,295

(22) Filed: Jan. 9, 2026

(30) Foreign Application Priority Data
Mar. 5, 2025 (JP) 2025-034809

(51) Int. Cl. H03K 17/16; H03K 17/28

(52) U.S. Cl. CPC H03K 17/16; H03K 17/28

(57) ABSTRACT

According to one embodiment, a semiconductor device includes a control signal input terminal, a switching element, and a controller. The switching element includes a first control terminal G1 and a second control terminal G2. The controller includes a control terminal G, an input terminal S, and an output terminal D. The controller includes a control switching element and a delay portion. The control switching element includes a control terminal Gs, an input terminal Ss, and an output terminal Ds. The delay portion includes an input terminal Din and an output terminal Dout. The delay portion outputs a control voltage Vd to the output terminal Dout after a lapse of a delay time td from a time when a voltage input to the input terminal Din is switched from a first voltage V1 to a second voltage V2.

### CROSS-REFERENCE TO RELATED APPLICATIONS

This application is based upon and claims the benefit of priority from Japanese Patent Application No. 2025-034809, filed on Mar. 5, 2025; the entire contents of which are incorporated herein by reference.

### FIELD

Embodiments described herein relate generally to a semiconductor device.

### BACKGROUND

For example, it is desirable to reduce losses in semiconductor devices, such as transistors.

### BRIEF DESCRIPTION OF THE DRAWINGS

FIG. 1 is an equivalent circuit diagram illustrating a semiconductor device according to a first embodiment;

FIG. 2 is a schematic diagram illustrating the semiconductor device according to the first embodiment;

FIG. 3 is an equivalent circuit diagram illustrating the semiconductor device according to the first embodiment;

FIG. 4 is a schematic diagram illustrating a semiconductor device according to the first embodiment;

FIG. 5 is a graph illustrating characteristics of a control circuit according to the first embodiment;

FIG. 6 is a graph illustrating characteristics of the control circuit according to the first embodiment;

FIG. 7 is an equivalent circuit diagram illustrating a semiconductor device according to the first embodiment;

FIG. 8 is a graph illustrating characteristics of a control circuit according to the first embodiment;

FIG. 9 is a schematic diagram illustrating a semiconductor device according to the first embodiment;

FIG. 10 is a graph illustrating characteristics of a control circuit according to the first embodiment;

FIG. 11 is a graph illustrating characteristics of the control circuit according to the first embodiment;

FIG. 12 is a schematic diagram illustrating a semiconductor device according to the first embodiment;

FIG. 13 is a graph illustrating characteristics of a control circuit according to the first embodiment;

FIG. 14 is a graph illustrating characteristics of the control circuit according to the first embodiment;

FIG. 15 is a schematic diagram illustrating a semiconductor device according to the first embodiment;

FIG. 16 is a graph illustrating characteristics of a control circuit according to the first embodiment;

FIG. 17 is a schematic diagram illustrating a semiconductor device according to the first embodiment; and

FIG. 18 is a graph illustrating characteristics of a control circuit according to the first embodiment.

### DETAILED DESCRIPTION

According to one embodiment, a semiconductor device includes a control signal input terminal, a switching element, and a controller. The switching element includes a first control terminal G1 and a second control terminal G2. The controller includes a control terminal G, an input terminal S, and an output terminal D. The controller includes a control switching element and a delay portion. The control switching element includes a control terminal Gs, an input terminal Ss, and an output terminal Ds. The delay portion includes an input terminal Din and an output terminal Dout. The delay portion is configured to output a control voltage Vd to the output terminal Dout after a lapse of a delay time td from a time when a voltage input to the input terminal Din is switched from a first voltage V1 to a second voltage V2. The input terminal Ss of the control switching element is electrically connected to the input terminal S of the controller. The output terminal Ds of the control switching element is electrically connected to the output terminal D of the controller. The input terminal Din of the delay portion is electrically connected to the control terminal G of the controller. The output terminal Dout of the delay portion is electrically connected to the control terminal Gs of the control switching element. The first control terminal G1 of the switching element is electrically connected to the input terminal S of the controller. The second control terminal G2 of the switching element is electrically connected to the output terminal D of the controller.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

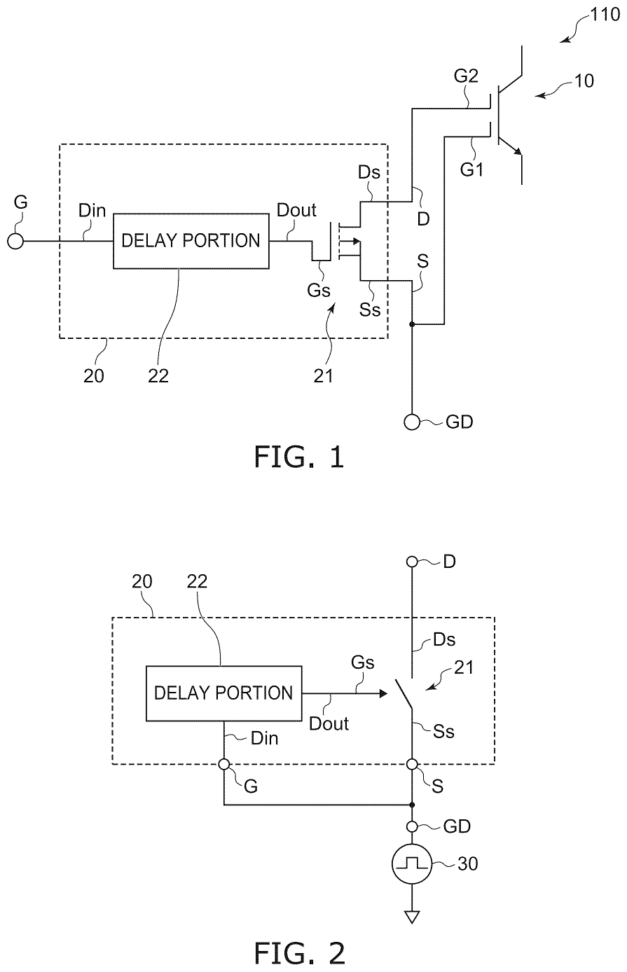

FIG. 1 is an equivalent circuit diagram illustrating a semiconductor device according to a first embodiment.

As shown in FIG. 1, a semiconductor device 110 according to the embodiment includes a control signal input terminal GD, a switching element 10, and a controller 20.

The switching element 10 includes at least two independent control terminals, namely, a first control terminal G1 and a second control terminal G2.

The controller 20 includes a control terminal G, an input terminal S, an output terminal D, a control switching element 21, and a delay portion 22. The control switching element 21 includes a control terminal Gs, an input terminal Ss, and an output terminal Ds. The delay portion 22 includes an input terminal Din and an output terminal Dout.

After a lapse of a delay time td from the time when a voltage input to the input terminal Din is switched from a first voltage V1 to a second voltage V2, the delay portion 22 outputs a control voltage Vd to the output terminal Dout.

The input terminal Ss of the control switching element 21 is electrically connected to the input terminal S of the controller 20. The output terminal Ds of the control switching element 21 is electrically connected to the output terminal D of the controller 20. The input terminal Din of the delay portion 22 is electrically connected to the control terminal G of the controller 20. The output terminal Dout of the delay portion 22 is electrically connected to the control terminal Gs of the control switching element 21.

The first control terminal G1 of the switching element 10 is electrically connected to the input terminal S of the controller 20. The second control terminal G2 of the switching element 10 is electrically connected to the output terminal D of the controller 20.

Since the control switching element 21 is provided in the embodiment, the first control terminal G1 and the second control terminal G2 of the switching element 10 can be controlled at different timings with one control signal input terminal GD. Since the two control terminals are controlled at different timings, for example, losses (for example, switching losses and conduction losses) can be reduced. According to the embodiment, a control circuit need not be provided for each control terminal. According to the embodiment, a semiconductor device capable of reducing losses can be provided with a simple circuit configuration.

The switching element 10 may be, for example, a vertical MOSFET or a vertical IGBT. In these transistors, a plurality of types of gates (for example, double-gate) are provided. Different control signals are supplied to the plurality of types of gates via the first control terminal G1 and the second control terminal G2.

The switching element 10 may include, for example, a control electrode provided on the back side. The switching element 10 may include, for example, an N-cathode region and a P-cathode region provided on the back side.

In one example, first voltage V1<second voltage V2 holds. In this case, when the voltage applied to the control terminal G of the controller 20 changes from the first voltage V1 to the second voltage V2, the control switching element 21 may turn on or turn off with a delay of the delay time td, which depends on the time constant of the delay portion 22.

In one example, first voltage V1>second voltage V2 holds. In this case, when the voltage applied to the control terminal G of the controller 20 changes from the first voltage V1 to the second voltage V2, the control switching element 21 may turn on or turn off with a delay time td′ (<td).

In one example, first voltage V1>second voltage V2 holds. In this case, when the voltage applied to the control terminal G of the controller 20 changes from the first voltage V1 to the second voltage V2, the control switching element 21 may turn on or turn on with a delay of a first delay time td1, which depends on the time constant of the delay portion 22.

In one example, first voltage V1<second voltage V2 holds. In this case, when the voltage applied to the control terminal G of the controller 20 changes from the first voltage V1 to the second voltage V2, the control switching element 21 may turn on or turn off with a delay of a second delay time td2 (<td1).

FIG. 2 is a schematic diagram illustrating the semiconductor device according to the first embodiment.

FIG. 2 illustrates the semiconductor device 110. A drive signal is input from a gate driver 30 to the delay portion 22. The delay portion 22 supplies the control voltage Vd to the control switching element 21 after a lapse of the delay time td from the time when the drive signal is output from the gate driver 30. As a result, the control switching element 21 enters the ON state or the OFF state. Accordingly, the drive signal is output from the output terminal D of the controller 20 with a delay of the delay time td.

An example of the delay portion 22 according to the embodiment will be described.

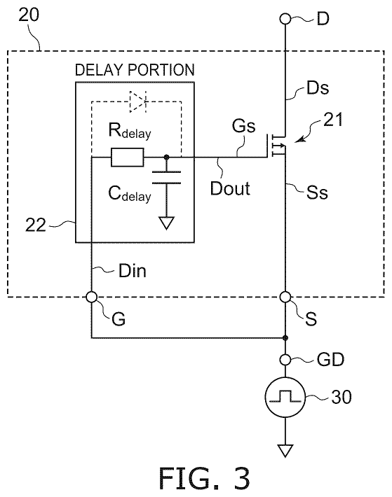

FIG. 3 is an equivalent circuit diagram illustrating the semiconductor device 110 according to the first embodiment.

As shown in FIG. 3, for example, the delay portion 22 includes a resistor R_{delay} and a capacitor C_{delay}. One end of the resistor R_{delay} is electrically connected to the input terminal Din of the delay portion 22. One end of the capacitor C_{delay} is electrically connected to the ground. The other end of the resistor R_{delay} is electrically connected to the other end of the capacitor C_{delay} and the output terminal Dout of the delay portion 22. The output terminal Dout of the delay portion 22 is electrically connected to the control terminal Gs of the control switching element 21. A signal input to the input terminal Din of the delay portion 22 is output from the output terminal Dout of the delay portion 22 after a lapse of a delay time that corresponds to the time constant of the resistor R_{delay} and the capacitor C_{delay}.

For example, the delay portion 22 may include at least any of a resistor, a coil, a capacitor, an operational amplifier, and a logic circuit.

In the semiconductor device 110 shown in FIG. 1, the connection from the control signal input terminal GD to the input terminal Ss of the control switching element 21 and the connection from the control terminal G of the controller 20 to the control terminal Gs of the control switching element 21 may include, for example, a connection via a capacitor. These connections may include, for example, a connection through which optical signals are transmitted and received by, for example, a photocoupler.

For example, any one or more elements among a diode, a switch, an operational amplifier, and a photocoupler may be interposed between the input terminal Din of the delay portion 22 and the control terminal Gs of the control switching element 21.

The semiconductor device 110 may further include another controller. One or more elements among a resistor, a coil, a capacitor, a diode, a switch, an operational amplifier, a photocoupler, and the other controller are interposed between the control signal input terminal GD and the input terminal S of the controller 20, between the control signal input terminal GD and the first control terminal G1 of the switching element 10, between the input terminal S of the controller 20 and the first control terminal G1 of the switching element 10, and between the output terminal D of the controller 20 and the second control terminal G2 of the switching element 10.

The control switching element 21 may include, for example, a transistor. The control switching element 21 may be, for example, any of a MOSFET, a bipolar transistor, an IGBT, a Gan-HEMT, and a Gan-HEMT cascode-connected to a MOSFET.

The control switching element 21 need not perform a body diode operation between, for example, the input terminal Ss of the control switching element 21 and the output terminal Ds of the control switching element 21.

The breakdown voltage of the control switching element 21 may be, for example, 20 V or more and 200 V or less.

In one example, the channel polarity of the control switching element 21 may be, for example, N-channel. The control switching element 21 may, for example, turn off at a gate voltage higher than a first threshold voltage. In another example, the channel polarity of the control switching element 21 may be, for example, P-channel. The control switching element 21 may, for example, turn off at a gate voltage lower than a second threshold voltage.

In one example, the control switching element 21 may be, for example, normally-off. The control switching element 21 may be, for example, in the OFF state when the voltage of the control terminal Gs of the control switching element 21 is zero volts. In another example, the control switching element 21 may be, for example, normally-on. The control switching element 21 may be, for example, in the ON state when the voltage of the control terminal Gs of the control switching element 21 is zero volts.

With the combinations of the channel polarity and normally-on/off of the control switching element 21, four types of functions are obtained.

For example, when the control switching element 21 is normally-on and P-channel, a turn-off delay circuit is configured. For example, when the control switching element 21 is normally-on and N channel, a turn-on delay circuit is configured. For example, when the control switching element 21 is normally-off and P-channel, a post-turn-on isolation circuit is configured. For example, when the control switching element 21 is normally-off and N channel, a post-turn-off isolation circuit is configured. With these combinations, various types of gate control methods can be implemented. With these combinations, control signals in which either voltage rise timings or voltage fall timings are different can be generated from one gate signal. A plurality of control signals in which either a plurality of voltage rise timings or a plurality of voltage fall timings are delayed can be generated from one gate signal.

For example, a part of the controller 20 may be integrated into the switching element 10.

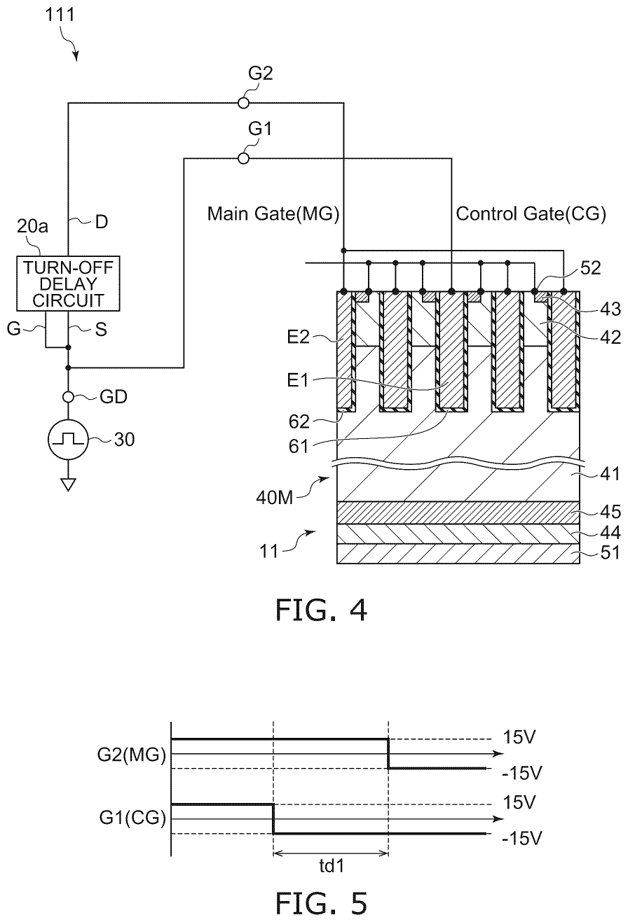

FIG. 4 is a schematic diagram illustrating a semiconductor device according to the first embodiment.

As shown in FIG. 4, a semiconductor device 111 according to the embodiment includes a turn-off delay circuit 20a and a semiconductor element 11. The turn-off delay circuit 20a is included in the controller 20. In the turn-off delay circuit 20a, the control switching element 21 is normally-on and P-channel. The semiconductor element 11 is a double-gate IGBT. The double-gate IGBT is an example of the switching element 10.

The semiconductor element 11 includes a first control electrode E1, a second control electrode E2, the first control terminal G1, and the second control terminal G2. The first control terminal G1 is electrically connected to the first control electrode E1. The second control terminal G2 is electrically connected to the second control electrode E2. The second control electrode E2 corresponds to a main gate (MG) of the semiconductor element 11. The first control electrode E1 corresponds to a control gate (CG) of the semiconductor element 11.

The output terminal of the gate driver 30 is electrically connected to the control signal input terminal GD of the turn-off delay circuit 20a. The control signal input terminal GD of the turn-off delay circuit 20a is electrically connected to the first control terminal G1 of the semiconductor element 11 and the input terminal S of the turn-off delay circuit 20a. The output terminal D of the turn-off delay circuit 20a is electrically connected to the second control terminal G2 of the semiconductor element 11.

As shown in FIG. 4, the semiconductor element 11 includes a first electrode 51, a second electrode 52, a first insulating region 61, a second insulating region 62, and a semiconductor member 40M. The semiconductor member 40M is provided between the first electrode 51 and the second electrode 52. The semiconductor member 40M includes a first semiconductor region 41 of a first conductivity type, a second semiconductor region 42 of a second conductivity type, a third semiconductor region 43 of the first conductivity type, and a fourth semiconductor region 44 of the second conductivity type. The second semiconductor region 42 is between the first electrode 51 and the second electrode 52. The third semiconductor region 43 is between the second semiconductor region 42 and the second electrode 52. The second electrode 52 is electrically connected to the third semiconductor region 43. The fourth semiconductor region 44 is between the first electrode 51 and the first semiconductor region 41. The fourth semiconductor region 44 is electrically connected to the first electrode 51. The first insulating region 61 is provided between the first control electrode E1 and the first semiconductor region 41, the second semiconductor region 42, the third semiconductor region 43, and the second electrode 52. The second insulating region 62 is provided between the second control electrode E2 and the first semiconductor region 41, the second semiconductor region 42, the third semiconductor region 43, and the second electrode 52. The first insulating region 61 and the second insulating region 62 are in contact with the first semiconductor region 41, the second semiconductor region 42 and the third semiconductor region 43. The first semiconductor region 41, the second semiconductor region 42, and the third semiconductor region 43 face the first control electrode E1 and the second control electrode E2. In a second direction X, the first insulating region 61 and the second insulating region 62 are located between two third semiconductor regions 43 next to each other and are in contact with the two third semiconductor regions 43. The first electrode 51 is, for example, a collector electrode. The second electrode 52 is an emitter electrode. A direction from the first electrode 51 toward the second electrode 52 is defined as a first direction Z. One of the directions intersecting with the first direction Z is defined as the second direction X. The second direction X is, for example, orthogonal to the first direction Z. In the second direction X, the first control electrode E1 and the second control electrode E2 face the second semiconductor region 42. The first control electrode E1 and the second control electrode E2 are electrically independent of each other and are connected to different control terminals, and different signals are input thereto. The first control electrode E1 and the second control electrode E2 may have the same shapes or may have different structures.

FIG. 5 is a graph illustrating characteristics of a control circuit according to the first embodiment.

FIG. 5 shows signals input to the first control terminal G1 and the second control terminal G2 of the semiconductor element 11.

A signal for turning off the semiconductor element 11 is called as a turn-off signal. The turn-off signal is a signal that drops from the first voltage V1 higher than a threshold voltage of the semiconductor element 11 to the second voltage V2 lower than the threshold voltage. A signal for turning on the semiconductor element 11 is called as a turn-off signal. The turn-off signal is a signal that rises from the second voltage V2 lower than the threshold voltage of the semiconductor element 11 to the first voltage V1 higher than the threshold voltage. As shown in FIG. 5, the turn-off signal input to the second control terminal G2 of the semiconductor element 11 (double-gate IGBT) is delayed from the turn-off signal input to the first control terminal G1 by the first delay time td1.

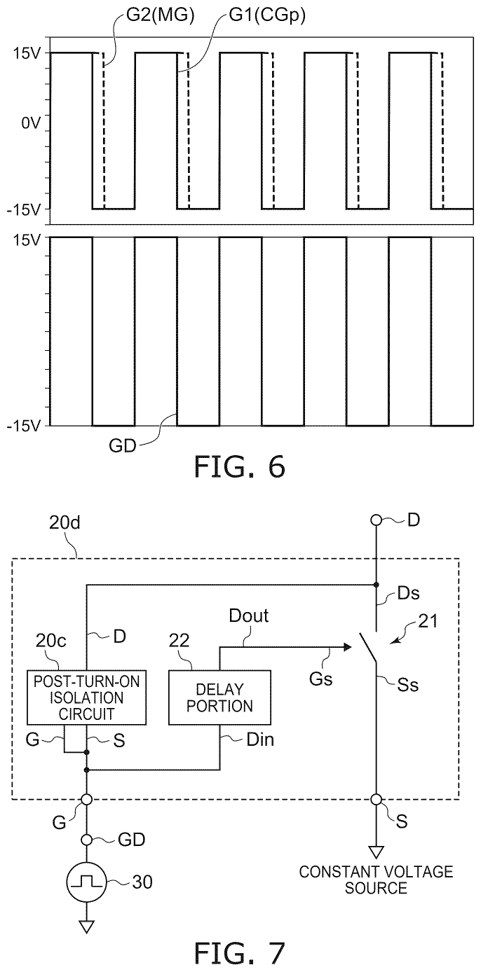

FIG. 6 is a graph illustrating characteristics of the control circuit according to the first embodiment.

FIG. 6 shows a signal input from the gate driver 30 and signals input to the first control terminal G1 and the second control terminal G2 of the semiconductor element 11. As one example, an example is shown in which the threshold value of the semiconductor element 11 is 10 V, the first voltage is 15 V, and the second voltage is −15 V.

As shown in FIG. 6, the turn-on signal from the gate driver 30 is input to the first control terminal G1 and the second control terminal G2 of the semiconductor element 11. The turn-off signal from the gate driver 30 is input to the first control terminal G1. The turn-off signal from the gate driver 30 is delayed and input to the second control terminal G2.

FIG. 7 is an equivalent circuit diagram illustrating a semiconductor device according to the first embodiment.

As shown in FIG. 7, a pulse generation circuit 20d includes a post-turn-on isolation circuit 20c, the delay portion 22, the control switching element 21 of N-channel, the input terminal S, and the output terminal D. The post-turn-on isolation circuit 20c is the controller 20 in which the control switching element 21 is normally-off and P-channel.

The output terminal of the gate driver 30 is electrically connected to the control signal input terminal GD. The control signal input terminal GD is electrically connected to the input terminal S of the post-turn-on isolation circuit 20c and the input terminal Din of the delay portion 22. The output terminal Dout of the delay portion 22 is electrically connected to the control terminal Gs of the control switching element 21. The input terminal Ss of the control switching element 21 is electrically connected to the ground or a constant voltage source. The output terminal Ds of the control switching element 21 is electrically connected to the output terminal D of the post-turn-on isolation circuit 20c and the output terminal D of the pulse generation circuit 20d.

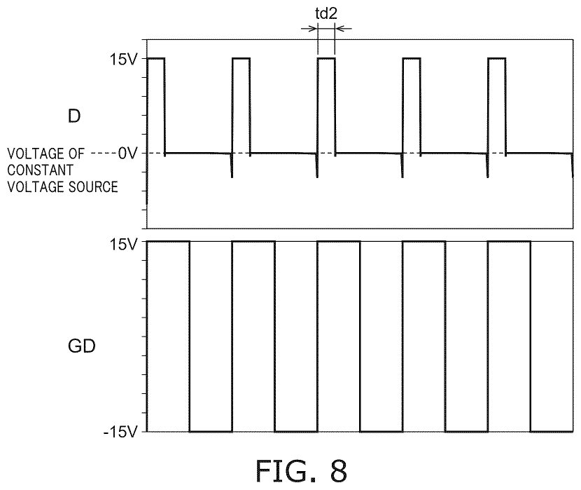

FIG. 8 is a graph illustrating characteristics of a control circuit according to the first embodiment.

FIG. 8 shows the voltages of the control signal input terminal GD and the output terminal D of the pulse generation circuit 20d.

As shown in FIG. 8, the input turn-on signal is output from the output terminal. After a lapse of the second delay time td2 from the turn-on signal output from the output terminal, the voltage of the constant voltage source is output from the output terminal. The pulse generation circuit 20d generates a pulse for a certain period from the turn-on.

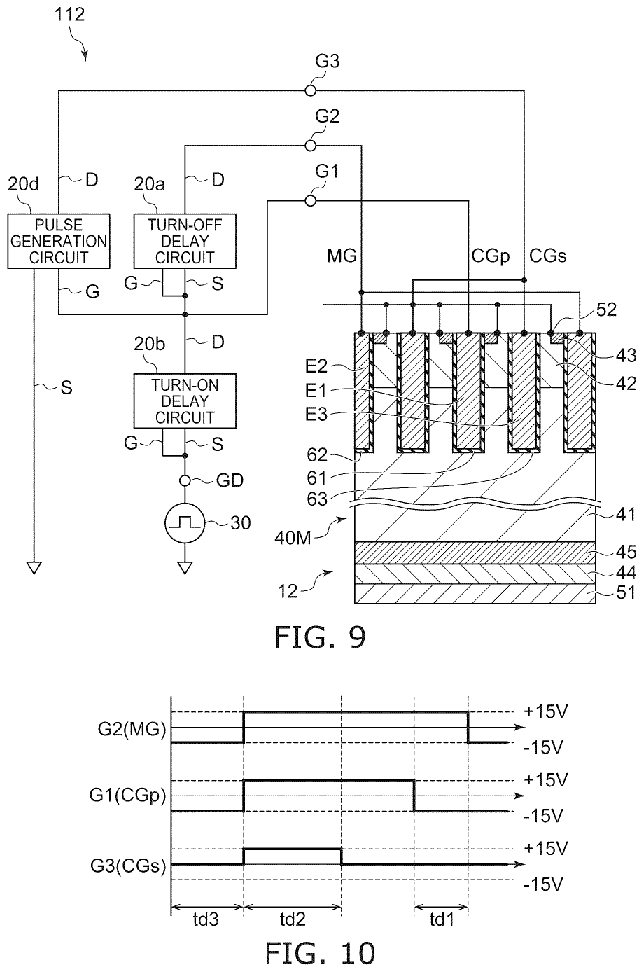

FIG. 9 is a schematic diagram illustrating a semiconductor device according to the first embodiment.

As shown in FIG. 9, a semiconductor device 112 according to the embodiment includes the turn-off delay circuit 20a, a turn-on delay circuit 20b, the pulse generation circuit 20d, and a semiconductor element 12. The semiconductor element 12 is a triple-gate IGBT. The triple-gate IGBT is an example of the switching element 10. The semiconductor element 12 includes three types of independent control electrodes and control terminals.

The semiconductor element 12 includes the first control electrode E1, the second control electrode E2, a third control electrode E3, the first control terminal G1, the second control terminal G2, and a third control terminal G3. The first control terminal G1 is electrically connected to the first control electrode E1. The second control terminal G2 is electrically connected to the second control electrode E2. The third control terminal G3 is electrically connected to the third control electrode E3. The second control electrode E2 corresponds to a main gate (MG) of the semiconductor element 12. The first control electrode E1 corresponds to a control gate (CGp) of the semiconductor element 12. The third control electrode E3 corresponds to a control gate (CGs) of the semiconductor element 12. A third insulating region 63 is provided between the third control electrode E3 and the first semiconductor region 41, the second semiconductor region 42, the third semiconductor region 43, and the second electrode 52. The first semiconductor region 41, the second semiconductor region 42, and the third semiconductor region 43 face the third control electrode E3. The third control electrode E3 may have, for example, a structure the same as or different from the structure of the first control electrode E1.

The output terminal of the gate driver 30 is electrically connected to the control signal input terminal GD. The control signal input terminal GD is electrically connected to the input terminal S of the turn-on delay circuit 20b. The output terminal D of the turn-on delay circuit 20b is electrically connected to the input terminal S of the turn-off delay circuit 20a, the input terminal S of the pulse generation circuit 20d, and the first control terminal G1 of the semiconductor element 12. The output terminal D of the turn-off delay circuit 20a is electrically connected to the second control terminal G2 of the semiconductor element 12. The output terminal D of the pulse generation circuit 20d is electrically connected to the third control terminal G3 of the semiconductor element 12.

FIG. 10 is a graph illustrating characteristics of a control circuit according to the first embodiment.

FIG. 10 shows signals input to the first control terminal G1, the second control terminal G2, and the third control terminal G3 of the semiconductor element 12 (triple-gate IGBT).

As shown in FIG. 10, a pulse having the width of the second delay time td2 is input to the third control terminal G3 of the semiconductor element 12. The turn-off signal input to the second control terminal G2 is delayed from the turn-off signal input to the first control terminal G1 by the first delay time td1.

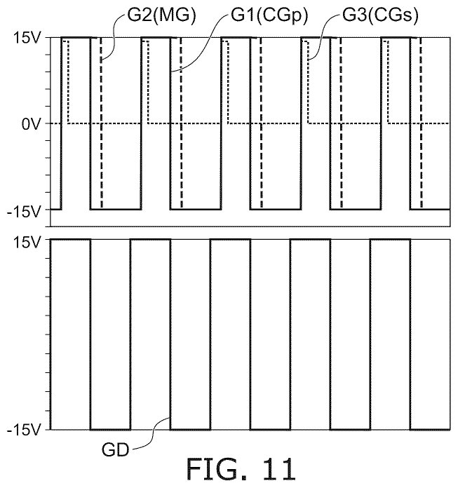

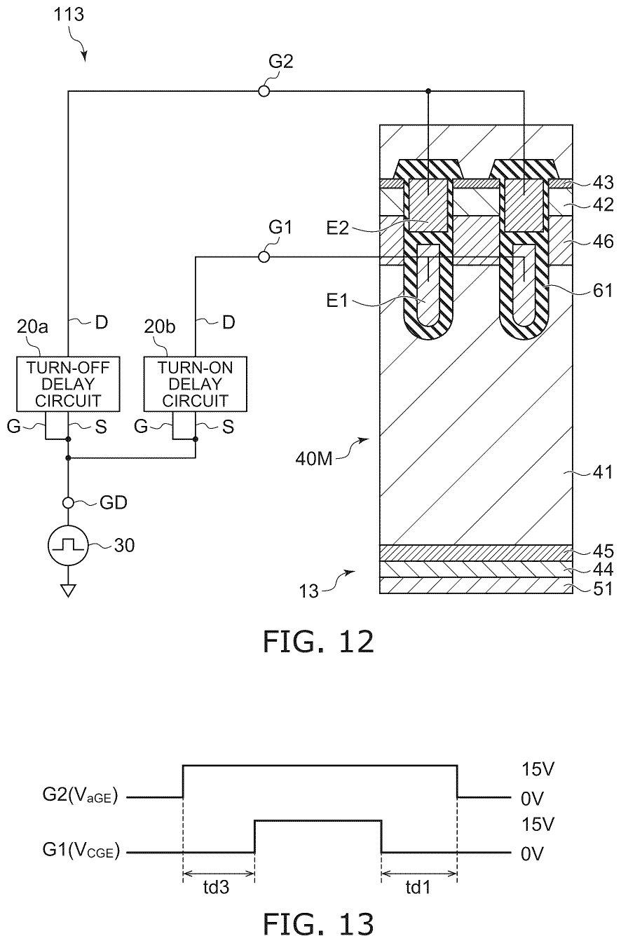

FIG. 11 is a graph illustrating characteristics of the control circuit according to the first embodiment.

FIG. 11 shows a signal input from the gate driver 30 and signals input to the first control terminal G1, the second control terminal G2, and the third control terminal G3 of the semiconductor element 12.

As shown in FIG. 11, the turn-on signal of the gate driver 30 is delayed and input to the first control terminal G1, the second control terminal G2, and the third control terminal G3 of the semiconductor element 12. The voltage of the constant voltage source is delayed from the turn-on signal input to the third control terminal G3 and is input to the third control terminal G3. The turn-off signal from the gate driver 30 is input to the first control terminal G1. The turn-off signal from the gate driver 30 is delayed and input to the second control terminal G2.

As shown in FIG. 9, in the semiconductor element 12, the first semiconductor region 41 may include a fifth semiconductor region 45 of the first conductivity type. The fifth semiconductor region 45 is in contact with the fourth semiconductor region 44. The fifth semiconductor region 45 is, for example, a buffer layer.

FIG. 12 is a schematic diagram illustrating a semiconductor device according to the first embodiment.

As shown in FIG. 12, a semiconductor device 113 according to the embodiment includes the turn-off delay circuit 20a, the turn-on delay circuit 20b, and a semiconductor element 13. The semiconductor element 13 is a split-gate IGBT. The split-gate IGBT is an example of the switching element 10.

The semiconductor element 13 is a trench-type device. In the semiconductor element 13, the first control electrode E1 and the second control electrode E2 are provided in one trench. The first control terminal G1 is electrically connected to the first control electrode E1. The second control terminal G2 is electrically connected to the second control electrode E2. In the first direction Z, the first control electrode E1 is located between a part of the first semiconductor region 41 and the second electrode 52. In the first direction Z, the second control electrode E2 is located between the first control electrode E1 and the second electrode 52. In the second direction X, the first control electrode E1 faces the first semiconductor region 41. In the second direction X, the second control electrode E2 faces the second semiconductor region 42 and the third semiconductor region 43.

The output terminal of the gate driver 30 is electrically connected to the control signal input terminal GD. The control signal input terminal GD is electrically connected to the input terminal S of the turn-off delay circuit 20a and the input terminal S of the turn-on delay circuit 20b. The output terminal D of the turn-off delay circuit 20a is electrically connected to the second control terminal G2 of the semiconductor element 13. The output terminal D of the turn-on delay circuit 20b is electrically connected to the first control terminal G1 of the semiconductor element 13. The turn-off delay circuit 20a and the turn-on delay circuit 20b may share one delay portion 22.

FIG. 13 is a graph illustrating characteristics of a control circuit according to the first embodiment.

FIG. 13 shows signals input to the first control terminal G1 and the second control terminal G2 of the semiconductor element 13.

As shown in FIG. 13, the turn-on signal input to the first control terminal G1 of the semiconductor element 13 is delayed from the turn-on signal input to the second control terminal G2 by a third delay time td3. The turn-off signal input to the second control terminal G2 of the semiconductor element 13 is delayed from the turn-off signal input to the first control terminal G1 by the first delay time td1.

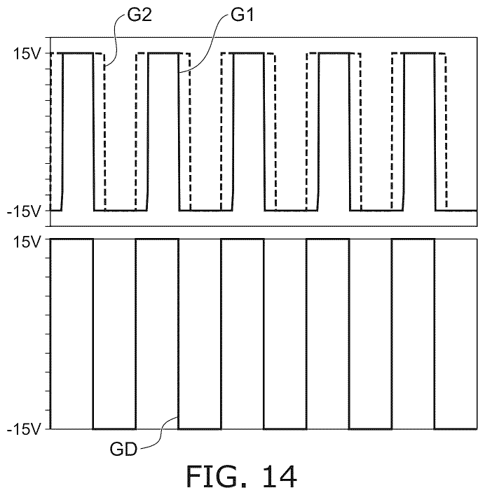

FIG. 14 is a graph illustrating characteristics of the control circuit according to the first embodiment.

FIG. 14 shows a signal input from the gate driver 30 and signals input to the first control terminal G1 and the second control terminal G2 of the semiconductor element 13.

As shown in FIG. 14, the turn-on signal from the gate driver 30 is input to the second control terminal G2 of the semiconductor element 13. The turn-on signal from the gate driver 30 is delayed by the third delay time td3 and is input to the first control terminal G1 of the semiconductor element 13. The turn-off signal from the gate driver 30 is input to the first control terminal G1. The turn-off signal from the gate driver 30 is delayed by the first delay time td1 and is input to the second control terminal G2.

As shown in FIG. 12, the semiconductor element 13 may include a sixth semiconductor region 46. The sixth semiconductor region 46 is between the first semiconductor region 41 and the second semiconductor region 42. The sixth semiconductor region 46 is, for example, of the first conductivity type. The first semiconductor region 41 may include the sixth semiconductor region 46. The first conductivity type impurity concentration of the sixth semiconductor region 46 is higher than that of the other part of the first semiconductor region 41. The sixth semiconductor region 46 is located between the first semiconductor region 41 and the second semiconductor region 42 in the first direction Z. In the second direction X, the first control electrode E1 faces the sixth semiconductor region 46. In the second direction X, the second control electrode E2 faces the sixth semiconductor region 46.

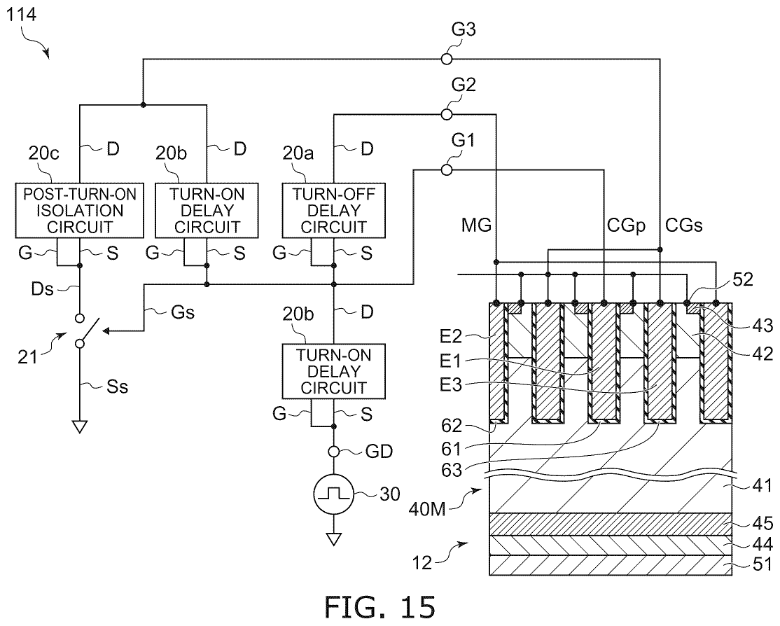

FIG. 15 is a schematic diagram illustrating a semiconductor device according to the first embodiment.

As shown in FIG. 15, a semiconductor device 114 according to the embodiment includes the turn-off delay circuit 20a, one turn-on delay circuit 20b, another turn-on delay circuit 20b, the post-turn-on isolation circuit 20c, the control switching element 21, and the semiconductor element 12. The semiconductor element 12 is a triple-gate IGBT. The triple-gate IGBT is an example of the switching element 10. The triple-gate IGBT includes three types of independent control electrodes.

The output terminal of the gate driver 30 is electrically connected to the control signal input terminal GD. The control signal input terminal GD is electrically connected to the input terminal S of the one turn-on delay circuit 20b and the control terminal G of the one turn-on delay circuit 20b. The output terminal D of the one turn-on delay circuit 20b is electrically connected to the input terminal S of the turn-off delay circuit 20a, the control terminal G of the turn-off delay circuit 20a, the input terminal S of the other turn-on delay circuit 20b, the control terminal G of the other turn-on delay circuit 20b, the control terminal Gs of the control switching element 21, and the first control terminal G1 of the semiconductor element 12. The output terminal D of the turn-off delay circuit 20a is electrically connected to the second control terminal G2 of the semiconductor element 12. The input terminal Ss of the control switching element 21 is electrically connected to a constant voltage source. The output terminal Ds of the control switching element 21 is electrically connected to the input terminal S of the post-turn-on isolation circuit 20c and the control terminal G of the post-turn-on isolation circuit 20c. The output terminal D of the post-turn-on isolation circuit 20c is electrically connected to the output terminal D of the other turn-on delay circuit 20b and the third control terminal G3 of the semiconductor element 12.

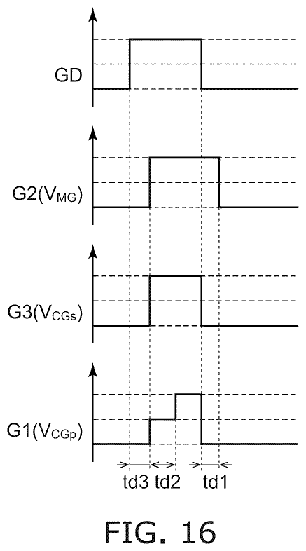

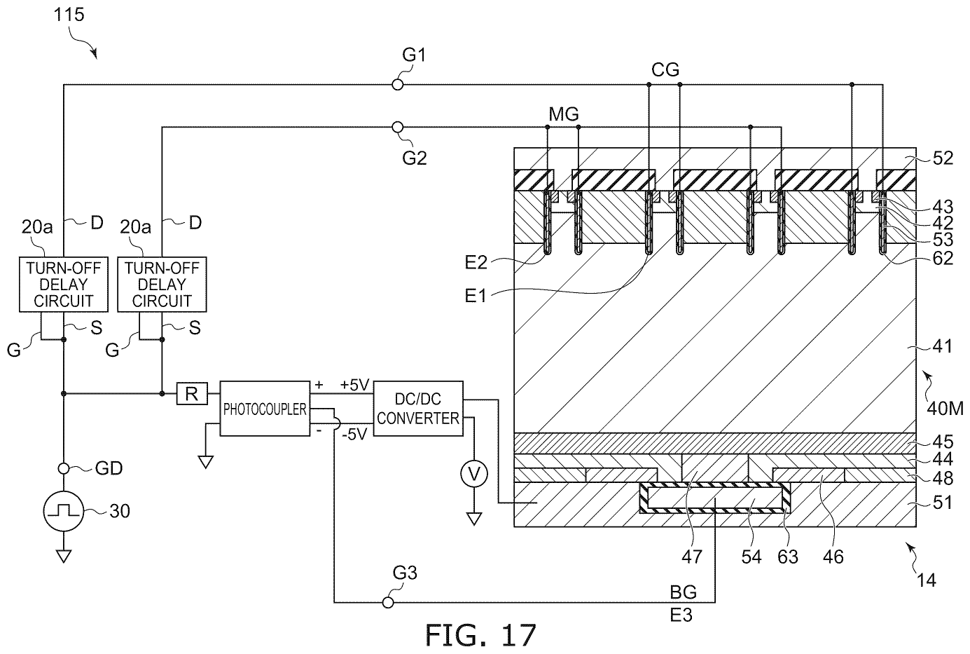

FIG. 16 is a graph illustrating characteristics of a control circuit according to the first embodiment.

FIG. 16 shows a signal input from the gate driver 30 and signals input to the first control terminal G1, the second control terminal G2, and the third control terminal G3 of the semiconductor element 12 in the semiconductor device 114.

As shown in FIG. 16, after the turn-on signal is input from the gate driver 30, the turn-on signal is input to the first control terminal G1, the second control terminal G2, and the third control terminal G3 of the semiconductor element 12 with a delay of the third delay time td3. The voltage of the signal input to the first control terminal G1 of the semiconductor element 12 is the same as the voltage of the constant voltage source. After the voltage of the constant voltage source is input to the first control terminal G1, the turn-on signal from the gate driver 30 is input to the first control terminal G1 with a delay of the second delay time td2. The turn-off signal from the gate driver 30 is input to the first control terminal G1 and the third control terminal G3. The turn-off signal from the gate driver 30 is delayed by the first delay time td1 and is input to the second control terminal G2. According to the embodiment, control signals of three different voltages can be input to the first control terminal G1.

FIG. 17 is a schematic diagram illustrating a semiconductor device according to the first embodiment.

As shown in FIG. 17, a semiconductor device 115 according to the embodiment includes one turn-off delay circuit 20a, another turn-off delay circuit 20a, a resistor, a photocoupler, a DC/DC converter, and a semiconductor element 14. The semiconductor element 14 is a double-sided gate IGBT. The double-sided gate IGBT includes at least two independent control electrodes on both sides of the semiconductor member 40M. In FIG. 17, a fourth electrode 54 of the planar gate type is provided on the back side of a vertical trench gate IGBT whose conduction is controlled by the second control electrode E2 provided on the front side of the semiconductor member 40M. The gate structure may be a trench gate structure or a planar gate structure. The double-sided gate IGBT is an example of the switching element 10.

As shown in FIG. 17, the semiconductor element 14 includes the first electrode 51, the second electrode 52, the third electrode 53, the fourth electrode 54, the first insulating region 61, the third insulating region 63, the first control electrode E1, the second control electrode E2, the third control electrode E3, and the semiconductor member 40M.

The semiconductor member 40M is provided between the first electrode 51 and the second electrode 52. The semiconductor member 40M includes the first semiconductor region 41 of the first conductivity type, the second semiconductor region 42 of the second conductivity type, the third semiconductor region 43 of the first conductivity type, the fourth semiconductor region 44 of the second conductivity type, the sixth semiconductor region 46 of the first conductivity type, a seventh semiconductor region 47 of the first conductivity type, and an eighth semiconductor region 48 of the second conductivity type.

The second semiconductor region 42 is between the first semiconductor region 41 and the second electrode 52. The third semiconductor region 43 is between at least a part of the second semiconductor region 42 and the second electrode 52. The second electrode 52 is electrically connected to the third semiconductor region 43.

The third insulating region 63 is between the third electrode 53 and the first semiconductor region 41, between the third electrode 53 and a part of the second semiconductor region 42, and between the third electrode 53 and the third semiconductor region 43. The third electrode 53 faces a part of the first semiconductor region 41, a part of the second semiconductor region 42, and a part of the third semiconductor region 43. The fourth semiconductor region 44 is between the first electrode 51 and the first semiconductor region 41. The sixth semiconductor region 46 is between the first electrode 51 and a part of the fourth semiconductor region 44.

The fourth semiconductor region 44 is between the first electrode 51 and the first semiconductor region 41. The sixth semiconductor region 46 is between the first electrode 51 and a part of the fourth semiconductor region 44. The seventh semiconductor region 47 is between the fourth electrode 54 and the first semiconductor region 41. The seventh semiconductor region 47 is between one fourth semiconductor region 44 and another fourth semiconductor region 44 in the second direction X. A part of the fourth semiconductor region 44 is between the seventh semiconductor region 47 and the sixth semiconductor region 46 in the second direction X. The eighth semiconductor region 48 is between the first electrode 51 and the fourth semiconductor region 44 in the first direction Z. A direction from the seventh semiconductor region 47 to the eighth semiconductor region 48 is along the second direction X. The sixth semiconductor region 46 is between a part of the fourth semiconductor region 44 and the eighth semiconductor region 48 in the second direction X. The first insulating region 61 is between the first electrode 51 and the fourth electrode 54, between the fourth electrode 54 and a part of the fourth semiconductor region 44, between the fourth electrode 54 and a part of the sixth semiconductor region 46, and between the fourth electrode 54 and the seventh semiconductor region 47. The fourth electrode 54 faces a part of the fourth semiconductor region 44, a part of the sixth semiconductor region 46, and the seventh semiconductor region 47. The fourth electrode 54 faces a part of the fourth semiconductor region 44, a part of the sixth semiconductor region 46, and the seventh semiconductor region 47 with the third insulating region 63 interposed therebetween. The first electrode 51 is connected to the sixth semiconductor region 46 and the eighth semiconductor region 48.

The fifth semiconductor region 45 of the first conductivity type may be further provided. The fifth semiconductor region 45 is between the fourth semiconductor region 44 and the first semiconductor region 41. The first conductivity type impurity concentration of the fifth semiconductor region 45 is higher than the first conductivity type impurity concentration of the first semiconductor region 41.

The first electrode 51 is, for example, a collector electrode. The second electrode 52 is, for example, an emitter electrode. The first control electrode E1 includes two third electrodes 53 facing one second semiconductor region 42. The second control electrode E2 includes two third electrodes 53 facing another second semiconductor region 42. The third control electrode E3 is electrically connected to the fourth electrode 54.

The output terminal of the gate driver 30 is electrically connected to the control signal input terminal GD. The control signal input terminal GD is electrically connected to the input terminal S of the one turn-off delay circuit 20a, the control terminal G of the one turn-off delay circuit 20a, the input terminal S of the other turn-off delay circuit 20a, the control terminal G of the other turn-off delay circuit 20a, and one end of the resistor. The other end of the resistor is electrically connected to the input terminal of the photocoupler. The output terminal of the photocoupler is electrically connected to the third control terminal G3. The resistor and the third control terminal G3 are electrically insulated. The photocoupler may be changed to an isolator.

The output terminal D of the one turn-off delay circuit 20a is electrically connected to the first control terminal G1. The output terminal D of the other turn-off delay circuit 20a is electrically connected to the second control terminal G2. The first control terminal G1 is electrically connected to the first control electrode E1 of the semiconductor element 14. The second control terminal G2 is electrically connected to the second control electrode E2 of the semiconductor element 14. The third control terminal G3 is electrically connected to the third control electrode E3.

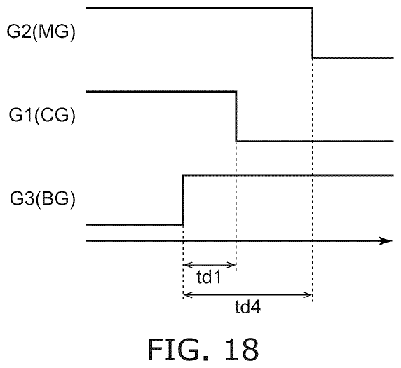

FIG. 18 is a graph illustrating characteristics of a control circuit according to the first embodiment.

FIG. 18 shows signals input to the first control terminal G1, the second control terminal G2, and the third control terminal G3 of the semiconductor element 14 in the semiconductor device 115.

As shown in FIG. 18, a turn-off signal input from the gate driver 30 is inverted by the photocoupler and is input to the third control terminal G3 as a turn-on signal. The turn-off signal is delayed by the first delay time td1 from the turn-on signal input to the third control terminal G3, and is input to the first control terminal G1. The turn-off signal is delayed by a fourth delay time td4 from the turn-on signal input to the third control terminal G3, and is input to the second control terminal G2. The first delay time td1 corresponds to the time constant of the one turn-off delay circuit 20a. The fourth delay time td4 corresponds to the time constant of the other turn-off delay circuit 20a.

According to the embodiment, a semiconductor device and a control circuit thereof capable of reducing switching losses and conduction losses can be provided.

The embodiment may include the following technical proposals.

### (Technical Proposal 1)

A semiconductor device comprising:
a control signal input terminal;
a switching element including a first control terminal G1 and a second control terminal G2; and
a controller including a control terminal G, an input terminal S, and an output terminal D,
the controller including
   a control switching element including a control terminal Gs, an input terminal Ss, and an output terminal Ds, and
   a delay portion,
the delay portion including an input terminal Din and an output terminal Dout,
the delay portion being configured to output a control voltage Vd to the output terminal Dout after a lapse of a delay time td from a time when a voltage input to the input terminal Din is switched from a first voltage V1 to a second voltage V2,
the input terminal Ss of the control switching element being electrically connected to the input terminal S of the controller,
the output terminal Ds of the control switching element being electrically connected to the output terminal D of the controller,
the input terminal Din of the delay portion being electrically connected to the control terminal G of the controller,
the output terminal Dout of the delay portion being electrically connected to the control terminal Gs of the control switching element,
the first control terminal G1 of the switching element being electrically connected to the input terminal S of the controller,
the second control terminal G2 of the switching element being electrically connected to the output terminal D of the controller.

### (Technical Proposal 2)

The semiconductor device according to Technical proposal 1, wherein the control switching element is a transistor.

### (Technical Proposal 3)

The semiconductor device according to any one of Technical proposals 1 to 2, wherein the control switching element is any of a MOSFET, a bipolar transistor, an IGBT, a Gan-HEMT, and a Gan-HEMT cascode-connected to a MOSFET.

### (Technical Proposal 4)

The semiconductor device according to any one of Technical proposals 1 to 3, wherein the control switching element is configured to not perform a body diode operation between the input terminal Ss and the output terminal Ds.

### (Technical Proposal 5)

The semiconductor device according to any one of Technical proposals 1 to 4, wherein a breakdown voltage of the control switching element is 20 V or more and 200 V or less.

### (Technical Proposal 6)

The semiconductor device according to any one of Technical proposals 1 to 5, wherein the control switching element is configured to turn off at a gate voltage higher than a first threshold voltage and to be in an OFF state at a gate voltage of zero volts.

### (Technical Proposal 7)

The semiconductor device according to any one of Technical proposals 1 to 5, wherein the control switching element is configured to turn off at a gate voltage lower than a second threshold voltage and to be in an OFF state at a gate voltage of zero volts.

### (Technical Proposal 8)

The semiconductor device according to any one of Technical proposals 1 to 5, wherein the control switching element is configured to turn off at a gate voltage higher than a first threshold voltage and to be in an ON state at a gate voltage of zero volts.

### (Technical Proposal 9)

The semiconductor device according to any one of Technical proposals 1 to 5, wherein the control switching element is configured to turn off at a gate voltage lower than a second threshold voltage and to be in an ON state at a gate voltage of zero volts.

### (Technical Proposal 10)

The semiconductor device according to any one of Technical proposals 1 to 9, wherein a connection from the control signal input terminal to the input terminal Ss of the control switching element and a connection from the control terminal G of the controller to the control terminal Gs of the control switching element include a connection via a capacitor or a connection through which an optical signal is transmitted and received by a photocoupler or another device.

### (Technical Proposal 11)

The semiconductor device according to any one of Technical proposals 1 to 10, wherein any one or more elements among a resistor, a coil, a capacitor, a diode, a switch, an operational amplifier, and a photocoupler are interposed between the output terminal Dout of the delay portion and the control terminal Gs of the control switching element.

### (Technical Proposal 12)

The semiconductor device according to any one of Technical proposals 1 to 11, wherein any one or more elements among a diode, a switch, an operational amplifier, and a photocoupler are interposed between the input terminal Din of the delay portion and the control terminal Gs of the control switching element.

### (Technical Proposal 13)

The semiconductor device according to any one of Technical proposals 1 to 12, wherein the delay portion includes at least any of a resistor, a coil, a capacitor, an operational amplifier, and a logic circuit.

### (Technical Proposal 14)

The semiconductor device according to any one of Technical proposals 1 to 13, wherein
the semiconductor device further includes another controller, and
one or more elements among a resistor, a coil, a capacitor, a diode, a switch, an operational amplifier, a photocoupler, and the other controller are interposed between the control signal input terminal and the input terminal S of the controller, between the control signal input terminal and the first control terminal G1 of the switching element, between the input terminal S of the controller and the first control terminal G1 of the switching element, and between the output terminal D of the controller and the second control terminal G2 of the switching element.

### (Technical Proposal 15)

The semiconductor device according to Technical proposal 14, wherein the control terminal G of the controller is electrically connected to any of the input terminal S, an input terminal S′ of the other controller, and an output terminal D′ of the other controller.

### (Technical Proposal 16)

The semiconductor device according to any one of Technical proposals 1 to 15, wherein the switching element is a vertical MOSFET or a vertical IGBT.

### (Technical Proposal 17)

The semiconductor device according to any one of Technical proposals 1 to 16, wherein the switching element includes a first control electrode E1, a second control electrode E2, and a third control electrode E3.

### (Technical Proposal 18)

The semiconductor device according to any one of Technical proposals 1 to 17, wherein the switching element includes a control electrode on a back side.

### (Technical Proposal 19)

The semiconductor device according to any one of Technical proposals 1 to 18, wherein the switching element includes an N-cathode region and a P-cathode region on a back side.

### (Technical Proposal 20)

The semiconductor device according to any one of Technical proposals 1 to 16, wherein the switching element is a trench-type device and includes a first control electrode E1 and a second control electrode E2 in one trench, and the first control terminal G1 and the second control terminal G2 are connected to any of the first control electrode E1 and the second control electrode E2, respectively.

### (Technical Proposal 21)

The semiconductor device according to any one of Technical proposals 1 to 20, wherein a part of the controller is integrated into the switching element.

### (Technical Proposal 22)

The semiconductor device according to any one of Technical proposals 1 to 21, wherein the control switching element is configured to, when a voltage applied to the control terminal G of the controller changes from a first voltage V1 to a second voltage V2, turn on or off with a delay of a delay time td that depends on a time constant of the delay portion in a case of the first voltage V1<the second voltage V2, and turn on or off with a delay time td′ (<td) in a case of the first voltage V1>the second voltage V2.

### (Technical Proposal 23)

The semiconductor device according to any one of Technical proposals 1 to 22, wherein the control switching element is configured to, when a voltage applied to the control terminal G of the controller changes from a first voltage V1 to a second voltage V2, turn on or off with a delay of a delay time td1 that depends on a time constant of the delay portion in a case of the first voltage V1>the second voltage V2, and turn on or off with a delay time td2 (<td1) in a case of the first voltage V1<the second voltage V2.

### (Technical Proposal 24)

The semiconductor device according to any one of Technical proposals 1 to 23, wherein a change in a voltage applied to the second control terminal G2 of the switching element is delayed from a change in a voltage of the first control terminal G1 by a time that depends on a time constant of the delay portion.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, wiring members, semiconductor members, semiconductor regions, conductive members, insulating regions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and semiconductor modules practicable by an appropriate design modification by one skilled in the art based on the semiconductor devices and the semiconductor modules described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a control signal input terminal;
a switching element including a first control terminal G1 and a second control terminal G2; and
a controller including a control terminal G, an input terminal S, and an output terminal D,
the controller including
a control switching element including a control terminal Gs, an input terminal Ss, and an output terminal Ds, and
a delay portion,
the delay portion including an input terminal Din and an output terminal Dout,
the delay portion being configured to output a control voltage Vd to the output terminal Dout after a lapse of a delay time td from a time when a voltage input to the input terminal Din is switched from a first voltage V1 to a second voltage V2,
the input terminal Ss of the control switching element being electrically connected to the input terminal S of the controller,
the output terminal Ds of the control switching element being electrically connected to the output terminal D of the controller,
the input terminal Din of the delay portion being electrically connected to the control terminal G of the controller,
the output terminal Dout of the delay portion being electrically connected to the control terminal Gs of the control switching element,
the first control terminal G1 of the switching element being electrically connected to the input terminal S of the controller,
the second control terminal G2 of the switching element being electrically connected to the output terminal D of the controller.

2. The semiconductor device according to claim 1, wherein the control switching element is a transistor.

3. The semiconductor device according to claim 1, wherein the control switching element is any of a MOSFET, a bipolar transistor, an IGBT, a Gan-HEMT, and a Gan-HEMT cascode-connected to a MOSFET.

4. The semiconductor device according to claim 2, wherein the control switching element is configured to not perform a body diode operation between the input terminal Ss and the output terminal Ds.

5. The semiconductor device according to claim 2, wherein a breakdown voltage of the control switching element is 20 V or more and 200 V or less.

6. The semiconductor device according to claim 2, wherein the control switching element is configured to turn off at a gate voltage higher than a first threshold voltage and to be in an OFF state at a gate voltage of zero volts.

7. The semiconductor device according to claim 2, wherein the control switching element is configured to turn off at a gate voltage lower than a second threshold voltage and to be in an OFF state at a gate voltage of zero volts.

8. The semiconductor device according to claim 2, wherein the control switching element is configured to turn off at a gate voltage higher than a first threshold voltage and to be in an ON state at a gate voltage of zero volts.

9. The semiconductor device according to claim 2, wherein the control switching element is configured to turn off at a gate voltage lower than a second threshold voltage and to be in an ON state at a gate voltage of zero volts.

10. The semiconductor device according to claim 2, wherein a connection from the control signal input terminal to the input terminal Ss of the control switching element and a connection from the control terminal G of the controller to the control terminal Gs of the control switching element include a connection via a capacitor or a connection through which an optical signal is transmitted and received by a photocoupler or another device.

11. The semiconductor device according to claim 2, wherein any one or more elements among a resistor, a coil, a capacitor, a diode, a switch, an operational amplifier, and a photocoupler are interposed between the output terminal Dout of the delay portion and the control terminal Gs of the control switching element.

12. The semiconductor device according to claim 2, wherein any one or more elements among a diode, a switch, an operational amplifier, and a photocoupler are interposed between the input terminal Din of the delay portion and the control terminal Gs of the control switching element.

13. The semiconductor device according to claim 2, wherein the delay portion includes at least any of a resistor, a coil, a capacitor, an operational amplifier, and a logic circuit.

14. The semiconductor device according to claim 2, wherein
the semiconductor device further includes another controller, and
one or more elements among a resistor, a coil, a capacitor, a diode, a switch, an operational amplifier, a photocoupler, and the other controller are interposed between the control signal input terminal and the input terminal S of the controller, between the control signal input terminal and the first control terminal G1 of the switching element, between the input terminal S of the controller and the first control terminal G1 of the switching element, and between the output terminal D of the controller and the second control terminal G2 of the switching element.

15. The semiconductor device according to claim 14, wherein the control terminal G of the controller is electrically connected to any of the input terminal S, an input terminal S′ of the other controller, and an output terminal D′ of the other controller.

16. The semiconductor device according to claim 6, further comprising:
another delay portion; and
an N-channel control switching element,
the input terminal S of the controller being electrically connected to an input terminal of the other delay portion,
an output terminal of the other delay portion being electrically connected to a control terminal of the N-channel control switching element,
the output terminal D of the controller being electrically connected to an output terminal of the N-channel control switching element.

17. The semiconductor device according to claim 8, further comprising:
a second controller including a second delay portion and a second control switching element,
the second control switching element being configured to turn off at a gate voltage lower than a second threshold voltage and to be in an ON state at a gate voltage of zero volts,
an output terminal D of the second controller being electrically connected to the input terminal S of the controller.

18. The semiconductor device according to claim 8, further comprising:
a third controller including a third delay portion and a third control switching element,
the third control switching element being configured to turn off at a gate voltage lower than a second threshold voltage and to be in an ON state at a gate voltage of zero volts,
the third controller being interposed between the first control terminal G1 of the switching element and the input terminal S of the controller,
an output terminal of the third controller being electrically connected to the first control terminal G1 of the switching element,
an input terminal of the third controller being electrically connected to the input terminal S of the controller.
